(19) United States
(12) Patent Application Publication
(10) Pub. No.: US 2018/0287517 A1
(43) Pub. Date: Oct. 4, 2018

(54) PHASE CHANGE INHIBITED HEAT-TRANSFER THERMOELECTRIC POWER GENERATION DEVICE AND MANUFACTURING METHOD THEREOF

(71) Applicant: ZHEJIANG JIAXI OPTOELECTRONIC EQUIPMENT MANUFACTURING CO., LTD., Jiashan, Zhejiang (CN)

(72) Inventors: JIANZHONG ZHANG, Jiashan, Zhejiang (CN); JUQIANG LI, Jiashan, Zhejiang (CN)

(73) Assignee: ZHEJIANG JIAXI OPTOELECTRONIC EQUIPMENT MANUFACTURING CO., LTD., Jiashan, Zhejiang (CN)

(21) Appl. No.: 15/739,993

(22) PCT Filed: Aug. 3, 2016
(86) PCT No.: PCT/CN2016/093059

§ 371 Date: Apr. 20, 2018

(30) Foreign Application Priority Data
Aug. 6, 2015 (CN) 201510476809.6

(51) Int. Cl. H02N 11/00; H01L 35/30; H01L 35/32; H01L 35/34

(52) U.S. Cl. CPC H02N 11/002; H01L 35/34; H01L 35/32; H01L 35/30

(57) ABSTRACT

A phase change inhibition heat transfer thermoelectric power generation device and a method for manufacturing the same. The phase change inhibition heat transfer thermoelectric power generation device comprises at least one thermoelectric unit body, wherein the thermoelectric unit body comprises a P-type thermoelectric element, an N-type thermoelectric element, a phase change inhibition heat dissipation plate and a phase change inhibition heat collection plate. By adopting the phase change inhibition heat transfer thermoelectric power generation device provided by the present invention, the thermal resistance of ceramic plates and the contact thermal resistance between the ceramic plate and an electrode interface are decreased in a heat circuit, which is helpful to establish temperature difference. Since no interface thermal resistance exists, which greatly improves the heat-electricity conversion efficiency of the thermoelectric power generator. By combining a plurality of thermoelectric unit bodies, higher output voltage and higher output power can be obtained.

### TECHNICAL FIELD

The present invention relates to the field of energy, and in particular to a phase change inhibition heat transfer thermoelectric power generation device and a method for manufacturing the same.

### BACKGROUND

Seebeck effect was discovered by a German scientist named T. J. Seebeck in 1821. As illustrated in FIG. 1, a hot side 12 and a cold side 13 of both a P-type thermoelectric element 10 and an N-type thermoelectric element 11 are respectively connected by electrodes 14, thereby forming a traditional thermoelectric unit body. When inputting heat to the hot side of this thermoelectric unit body and making the temperature of the other side unchanged to establish temperature difference, electromotive force will be produced at both ends of a loop due to the Seebeck effect; after a load 15 is connected in the loop, electric power on the load will be obtained. This is a simplest thermoelectric power generator.

A practical thermoelectric power generation module usually consists of several pairs, tens of pairs, or even more pairs of thermoelectric unit bodies. The thermoelectric unit bodies (including P-type thermoelectric elements 10 and N-type thermoelectric elements 11) in a traditional thermoelectric power generation module are connected in series in an electric circuit and are connected in parallel in a heat circuit. As a complete thermoelectric power generation module, the outer sides of electrodes 14 on the hot side and the cold side are respectively integrated a piece of DBC ceramic plate 16 to electrically isolate from the outside. The thermoelectric power generation module is connected with an external load through a positive electrode 141 and a negative electrode 142, as illustrated in FIG. 2.

In the above-mentioned traditional thermoelectric power generation module, electrodes mainly serve as electrical connectors for P-type and N-type thermoelectric elements and also play a role of heat transfer. However, heat exchangers with a very large volume must be installed on two outer sides of the ceramic plates of the entire thermoelectric module to transfer needed heat into the thermoelectric module and dissipate needless heat into the environment. Thereby, a thermoelectric power generator is formed. A typical structure is illustrated in FIG. 3. The structure comprises a heat collector 17, a thermoelectric power generation module 18 and a radiator 19.

The above-mentioned traditional thermoelectric power generation module and the thermoelectric power generator can be used for manufacturing fuel gas or fuel oil thermoelectric power generator (system) or a radioactive isotope thermoelectric power generator, or can be used for solar thermal power generation, geothermal power generation, industrial waste heat power generation, automobile tail gas power generation, etc. Since there is no rotating part, the service life is long, and no noise is produced. It is an environment-friendly power source, and it has already been applied to various departments of national economy such as aerospace, industry, national defense and civil electrical appliances.

As for a traditional thermoelectric power generator, since the thermoelectric power generation module is connected with the hot side and the cold side of heat exchangers via ceramic plates, the most commonly used ceramic plates are aluminum oxide ceramic plates with thickness of 0.6 mm or 1 mm. The ceramic plates play a role of electrical insulation between the thermoelectric power generation module and the heat exchangers which are made of metal. However, at the same time, in a heat transfer passage, on both hot and cold sides, interface thermal resistance between the ceramic plates and the heat exchangers, thermal resistance of the ceramic plates and contact thermal resistance between the ceramic plates and electrodes of thermoelectric unit bodies will cause a great heat loss. The greater the temperature difference between hot side and cold side is, the greater the thermal resistance and the heat loss will be.

Another problem is that, in the traditional thermoelectric power generator, the thermoelectric power generation module must be configured with heat exchangers with large volume and heavy weight. In a most commonly used method, rib-shaped aluminum radiators are used on the cold side, and forced air cooling is further adopted, which not only increases the overall weight and volume of the thermoelectric power generator, but also reduces the reliability of the entire generator.

To overcome the disadvantages of the traditional thermoelectric power generation device, the present invention provides a thermoelectric power generation device having a new structure and further provides a method for manufacturing the same.

### SUMMARY

In view of the disadvantages of prior art, the purpose of the present invention is to provide a phase change inhibition heat transfer thermoelectric power generation device and a method for manufacturing the same so as to solve the problem that interface thermal resistance between ceramic plates and heat exchangers, thermal resistance of ceramic plates and contact thermal resistance between ceramic plates and electrodes of thermoelectric unit bodies will cause a very great heat loss because the thermoelectric power generation module is connected with the hot side and the cold side of heat exchangers via ceramic plates. The larger the heat flow density between hot side and cold side is, the greater the temperature difference loss caused by thermal resistance and the heat loss will be. Thereby, the heat-electricity conversion efficiency of the thermoelectric power generation device is reduced.

In order to realize the above-mentioned and other related purposes, the present invention provides a phase change inhibition heat transfer thermoelectric power generation device; and the phase change inhibition heat transfer thermoelectric power generation device comprises at least one thermoelectric unit body; the thermoelectric unit body comprises a P-type thermoelectric element, an N-type thermoelectric element, a phase change inhibition heat dissipation plate and a phase change inhibition heat collection plate.

The P-type thermoelectric element, the N-type thermoelectric element, the phase change inhibition heat dissipation plate and the phase change inhibition heat collection plate are arranged in parallel; the phase change inhibition heat collection plate is located between the P-type thermoelectric element and the N-type thermoelectric element, and the phase change inhibition heat dissipation plate is located on one side, far away from the phase change inhibition heat collection plate, of the P-type thermoelectric element or the N-type thermoelectric element; the P-type thermoelectric element, the N-type thermoelectric element, the phase change inhibition heat dissipation plate and the phase change inhibition heat collection plate are closely fit.

As one preferred solution of the phase change inhibition heat transfer thermoelectric power generation device provided by the present invention, each of the phase change inhibition heat dissipation plate and the phase change inhibition heat collection plate comprises a metal plate; a closed pipe having a certain shape is formed in the metal plate; and a heat transfer medium is filled in the closed pipe.

As one preferred solution of the phase change inhibition heat transfer thermoelectric power generation device provided by the present invention, each of the phase change inhibition heat dissipation plate and the phase change inhibition heat collection plate comprises two stacked metal plates; a closed pipe having a certain shape is formed in one metal plate; a heat transfer medium is filled in the closed pipe; a fluid medium pipe having a certain shape is formed in the other metal plate; openings are formed at both ends of the fluid medium pipe; and the openings are adapted to be interconnected with a fluid medium source.

As one preferred solution of the phase change inhibition heat transfer thermoelectric power generation device provided by the present invention, the shape of the closed pipe is a hexagonal cellular shape, a circular cellular shape, a quadrilateral cellular shape, a shape formed by a plurality of U in tandem, a rhombic shape, a triangular shape, a circular ring shape or any combination of more than one of the shapes.

As one preferred solution of the phase change inhibition heat transfer thermoelectric power generation device provided by the present invention, materials of both the phase change inhibition heat dissipation plate and the phase change inhibition heat collection plate are copper, copper alloy, aluminum, aluminum alloy, titanium, titanium alloy, stainless steel or any combination of more than one of the materials.

As one preferred solution of the phase change inhibition heat transfer thermoelectric power generation device provided by the present invention, materials of the P-type thermoelectric element and the N-type thermoelectric element are doped pseudobinary bismuth telluride and solid solution thereof, pseudoternary bismuth telluride and solid solution thereof, doped lead telluride and solid solution thereof, germanium telluride and solid solution thereof, single-filled or multi-filled skutterudite thermoelectric materials, Half-Heusler thermoelectric materials, doped Si—Ge alloy and Zintl phase thermoelectric materials.

As one preferred solution of the phase change inhibition heat transfer thermoelectric power generation device provided by the present invention, surfaces of fitting parts between the phase change inhibition heat dissipation plate and the phase change inhibition heat collection plate, and between the P-type thermoelectric element and the N-type thermoelectric element are flat; and holes, shallow slots, protrusions, shutters or covering coating layers are formed in or on surfaces of other parts of the phase change inhibition heat dissipation plate and the phase change inhibition heat collection plate to enhance heat transfer.

As one preferred solution of the phase change inhibition heat transfer thermoelectric power generation device provided by the present invention, the phase change inhibition heat transfer thermoelectric power generation device comprises a plurality of thermoelectric unit bodies; and the plurality of thermoelectric unit bodies are serially combined and integrated to form the phase change inhibition heat transfer thermoelectric power generation device.

As one preferred solution of the phase change inhibition heat transfer thermoelectric power generation device provided by the present invention, both sides of the phase change inhibition heat transfer thermoelectric power generation device are respectively provided with a DBC ceramic plate; the DBC ceramic plate on one side of the phase change inhibition heat transfer thermoelectric power generation device is fit with the surfaces of the phase change inhibition heat dissipation plates in the thermoelectric unit bodies; and the DBC ceramic plate on the other side of the phase change inhibition heat transfer thermoelectric power generation device is connected with the P-type thermoelectric elements or the N-type thermoelectric elements in the thermoelectric unit bodies through one phase change inhibition heat dissipation plates.

As one preferred solution of the phase change inhibition heat transfer thermoelectric power generation device provided by the present invention, the P-type thermoelectric elements, the N-type thermoelectric elements, the phase change inhibition heat dissipation plates, the phase change inhibition heat collection plates and the DBC ceramic plates are fixedly connected through a soldering, brazing, crimping, friction welding or pressure welding process; the ceramic plates may also be replaced with plates made up of other materials which have electrical insulation and heat insulation functions and are compatible with the working temperature range of the thermoelectric power generation device provided by the present invention.

The present invention further provides a method for manufacturing a phase change inhibition heat transfer thermoelectric power generation device, the method comprises the following steps:

manufacturing P-type thermoelectric elements and N-type thermoelectric elements;

manufacturing phase change inhibition heat dissipation plates;

manufacturing phase change inhibition heat collection plates;

preparing DBC ceramic plates;

arranging the P-type thermoelectric elements, the N-type thermoelectric elements, the phase change inhibition heat dissipation plates, the phase change inhibition heat collection plates and the DBC ceramic plates in parallel; the phase change inhibition heat collection plates being located between the P-type thermoelectric elements and the N-type thermoelectric elements; the phase change inhibition heat dissipation plates being located on one side, far away from the phase change inhibition heat collection plates, of the P-type thermoelectric elements and the N-type thermoelectric elements; the DBC ceramic plates being located on outer sides of the outermost phase change inhibition heat dissipation plates; and fixedly connecting the P-type thermoelectric elements, the N-type thermoelectric elements, the phase change inhibition heat dissipation plates, the phase change inhibition heat collection plates and the DBC ceramic plates.

As one preferred solution of the method for manufacturing the phase change inhibition heat transfer thermoelectric power generation device provided by the present invention, a specific method for manufacturing the P-type thermoelectric elements and the N-type thermoelectric elements comprises the following steps:

respectively preparing a material of the P-type thermoelectric elements and a material of the N-type thermoelectric elements according to certain components and proportions;

respectively manufacturing thermoelectric rods by using the prepared material of the P-type thermoelectric elements and the prepared material of the N-type thermoelectric elements according to a conventional zone melting growth process;

cutting the thermoelectric rods into thermoelectric elements by using an inside diameter slicer, an outside diameter slicer or a wire cutter;

electroplating or spray-coating an Ni layer, an Ni alloy layer, an Mo layer, an Mo alloy layer, a Ti layer or a Ti alloy layer onto the thermoelectric elements as a buffer layer; and

electroplating or chemically plating an Sn layer onto the buffer layer.

As one preferred solution of the method for manufacturing the phase change inhibition heat transfer thermoelectric power generation device provided by the present invention, a specific method for manufacturing the P-type thermoelectric elements and the N-type thermoelectric elements comprises the following steps:

respectively preparing a material of the P-type thermoelectric elements and a material of the N-type thermoelectric elements according to certain components and proportions;

respectively manufacturing block materials by using the prepared material of the P-type thermoelectric elements and the prepared material of the N-type thermoelectric elements through hot-pressing, an SPS process, a mechanical alloying method or other powder metallurgical processes;

cutting the block materials into thermoelectric elements by using an inside diameter slicer, an outside diameter slicer or a wire cutter;

electroplating or spray-coating an Ni layer, an Ni alloy layer, an Mo layer, an Mo alloy layer, a Ti layer or a Ti alloy layer onto the thermoelectric elements as a buffer layer; and

electroplating or chemically plating an Sn layer onto the buffer layer.

As one preferred solution of the method for manufacturing the phase change inhibition heat transfer thermoelectric power generation device provided by the present invention, after the phase change inhibition heat dissipation plates and the phase change inhibition heat collection plates are manufactured, the method further comprises a step of performing metallization treatment to the phase change inhibition heat dissipation plates and the phase change inhibition heat collection plates.

As one preferred solution of the method for manufacturing the phase change inhibition heat transfer thermoelectric power generation device provided by the present invention, the P-type thermoelectric elements, the N-type thermoelectric elements, the phase change inhibition heat dissipation plates, the phase change inhibition heat collection plates and the DBC ceramic plates are fixedly connected through a soldering, brazing, crimping, friction welding or pressure welding process.

As described above, the phase change inhibition heat transfer thermoelectric power generation device and the method for manufacturing the same provided by the present invention have the following beneficial effects:

1. In the phase change inhibition heat transfer thermoelectric power generation device provided by the present invention, one P-type thermoelectric element and one N-type thermoelectric element are isolated from each other through one phase change inhibition heat collection plate and one phase change inhibition heat dissipation plate to form a pair of thermoelectric unit bodies. A plurality of thermoelectric unit bodies are serially combined and integrated to form a thermoelectric device, and no electrical isolation is not needed thereamong. Integrated phase change inhibition heat transfer plates not only serve as electrodes of thermoelectric unit bodies, but also serve as heat collection plates and heat dissipation plates. By adopting the phase change inhibition heat transfer thermoelectric power generation device provided by the present invention, the thermal resistance of ceramic plates and the contact thermal resistance between the ceramic plate and an electrode interface are decreased in a heat circuit, which is helpful to establish temperature difference. Since the phase change inhibition heat transfer plate serves as both an electrode and a heat exchanger of a hot side and a cold side, the interface thermal resistance is smaller, and the heat-electricity conversion efficiency of the thermoelectric power generator will be greatly improved. By combining a plurality of thermoelectric unit bodies, higher output voltage and higher output power can be obtained.

2. For the thermoelectric elements in the phase change inhibition heat transfer thermoelectric power generation device provided by the present invention, rods grown through zone melting (or block materials manufactured through hot-pressing or other powder metallurgical process) are cut into sheets, subjected to a proper surface treatment process, and then directly used as the thermoelectric elements. This process is different from the traditional thermoelectric element manufacturing process, i.e., manufacturing thermoelectric elements with a relative small rectangular section through a cutting process by using sheets. Thus the manufacturing process of the thermoelectric module is simplified, the material utilization ratio is improved, and the consumption and costs of raw materials are greatly reduced.

### BRIEF DESCRIPTION OF THE DRAWINGS

FIG. 1 illustrates a structural schematic view of a thermoelectric power generation unit in the prior art.

FIG. 2 illustrates a structural schematic view of a thermoelectric power generation module in the prior art.

FIG. 3 illustrates a structural schematic view of a thermoelectric power generator in the prior art.

FIG. 4 illustrates a structural schematic view of a phase change inhibition heat transfer power generation device provided by the present invention.

FIG. 5 illustrates a flowchart of a method for manufacturing a phase change inhibition heat transfer power generation device provided by the present invention.

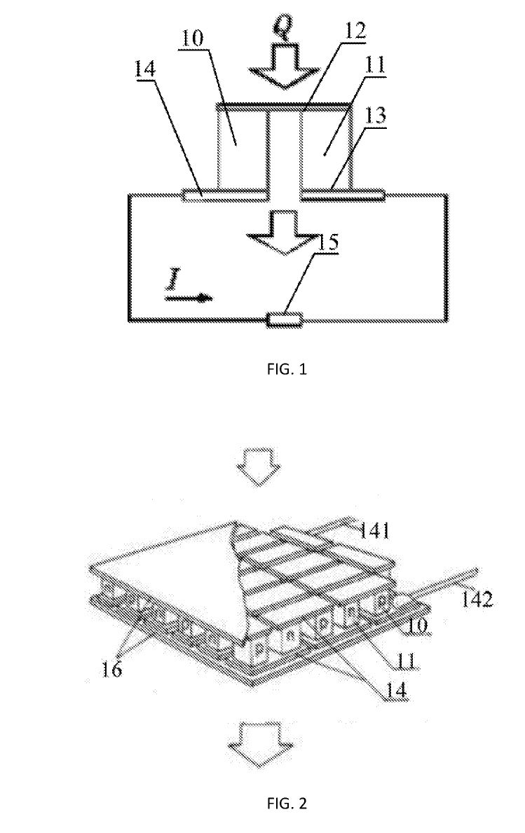

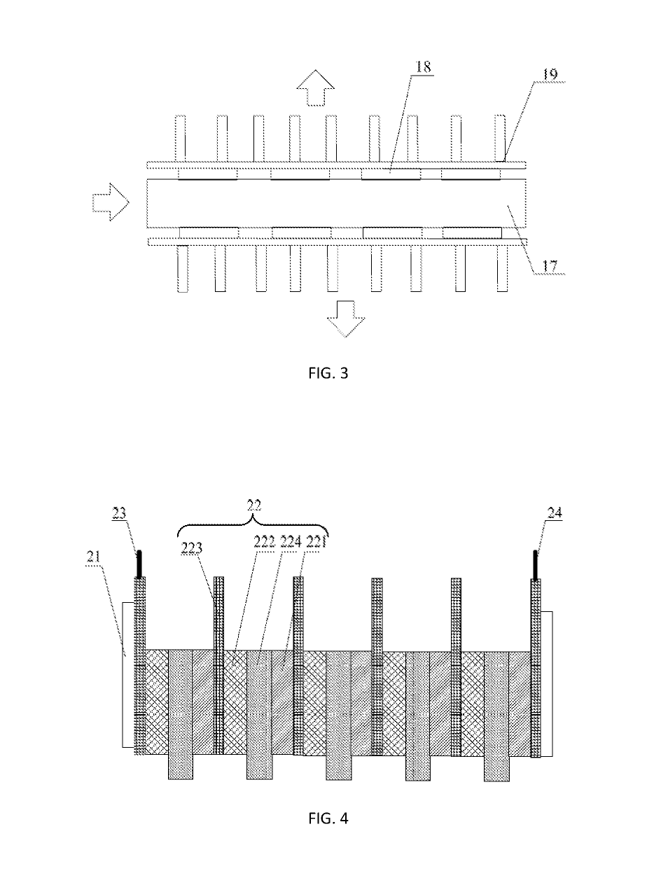

### DESCRIPTION OF COMPONENT REFERENCE SIGNS

10 P-type thermoelectric element
11 N-type thermoelectric element
12 Hot side
13 Cold side
14 Electrode
141 Positive electrode
142 Negative electrode
15 Load
16 DBC ceramic plate
17 Heat collector
18 Thermoelectric power generation module
19 Radiator
21 DBC ceramic plate
22 Thermoelectric unit body
221 P-type thermoelectric element
222 N-type thermoelectric element
223 Phase change inhibition heat dissipation plate
224 Phase change inhibition heat collection plate
23 Positive electrode
24 Negative electrode

### DETAILED DESCRIPTION OF THE PREFERRED EMBODIMENTS

The implementation modes of the present invention will be described below through specific examples. One skilled in the art can easily understand other advantages and effects of the present invention according to the content disclosed in the description. The present invention may also be implemented or applied through other different specific implementation modes. Various modifications or variations may be made to all details in the description based on different points of view and applications without departing from the spirit of the present invention.

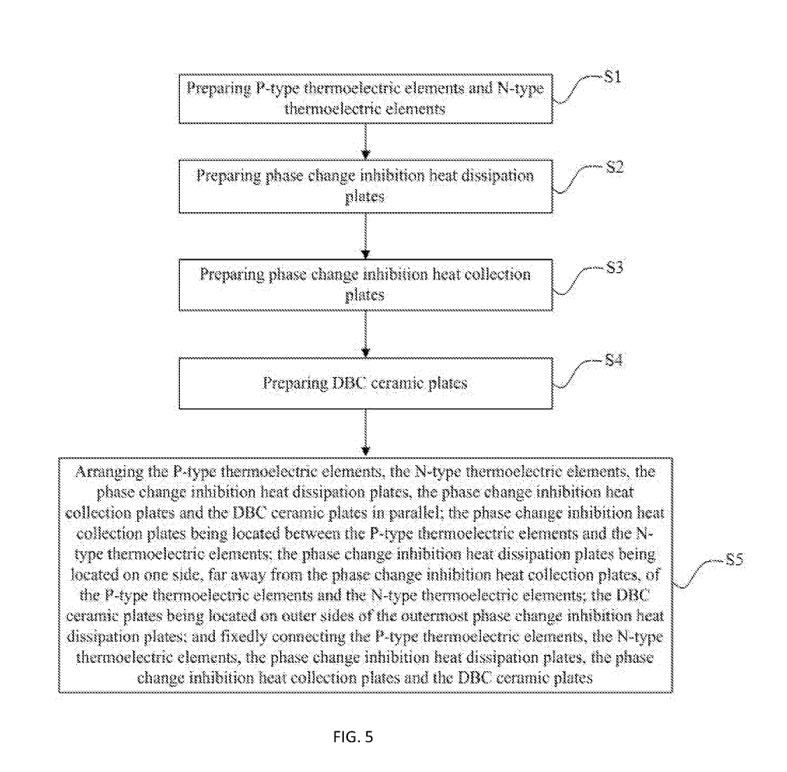

Please refer to FIG. 4 to FIG. 5. It needs to be stated that the drawings provided in the following embodiments are just used for schematically describing the basic concept of the present invention. Although the drawings merely illustrate components that are related to the present invention, rather than being drawn according to the numbers, shapes and sizes of components during actual implementation, the configuration, number and scale of each component during actual implementation thereof may be freely changed, and the component layout configuration thereof may be more complex.

### Embodiment 1

Please refer to FIG. 4. The present invention provides a phase change inhibition heat transfer thermoelectric power generation device. The phase change inhibition heat transfer thermoelectric power generation device comprises at least one thermoelectric unit body 22. The thermoelectric unit body 22 comprises a P-type thermoelectric element 221, an N-type thermoelectric element 222, a phase change inhibition heat dissipation plate 223 and a phase change inhibition heat collection plate 224.

The P-type thermoelectric element 221, the N-type thermoelectric element 222, the phase change inhibition heat dissipation plate 223 and the phase change inhibition heat collection plate 224 are arranged in parallel. The phase change inhibition heat collection plate 224 is located between the P-type thermoelectric element 221 and the N-type thermoelectric element 222, and the phase change inhibition heat dissipation plate 223 is located on one side, far away from the phase change inhibition heat collection plate 224, of the P-type thermoelectric element 221 or the N-type thermoelectric element 222. The P-type thermoelectric element 221, the N-type thermoelectric element 222, the phase change inhibition heat dissipation plate 223 and the phase change inhibition heat collection plate 224 are closely fit.

As an example, materials of the P-type thermoelectric element 221 and the N-type thermoelectric element 222 can be pseudobinary bismuth telluride Bi₂Te₃ and solid solution thereof, pseudoternary bismuth telluride and solid solution thereof, doped lead telluride PbTeand solid solution thereof (such as PbTe—SnTe and PbTe—SnTe—MnTe), germanium telluride GeTeand solid solution thereof (such as GeTe—PbTe and Ge—Te—AgSbTe₂), single-filled or multi-filled CoSb₃ skutterudite thermoelectric materials, Half-Heusler thermoelectric materials, doped Si—Ge alloy, Zintl phase thermoelectric materials and other thermoelectric materials.

As an example, for the P-type thermoelectric element 221 and the N-type thermoelectric element 222, rods grown through zone melting or block materials manufactured through hot-pressing, an SPS process, a mechanical alloying method or other powder metallurgical processes are cut into sheets, subjected to a proper surface treatment process and then directly used as the thermoelectric elements. This process is different from the traditional thermoelectric element manufacturing process, i.e., manufacturing thermoelectric elements with a relative small rectangular section through a cutting process by using sheets. Thus the manufacturing process of the thermoelectric module is simplified, the material utilization ratio is improved, and the consumption and costs of raw materials are greatly reduced. By connecting a plurality of unit bodies in series or in parallel, higher output power can be obtained. The thermoelectric power generation device manufactured in this embodiment facilitates the design of high-output-current thermoelectric power generators.

As an example, the phase change inhibition heat dissipation plate 223 comprises a metal plate. A closed pipe having a certain shape is formed in the metal plate through a blowing process. A heat transfer medium is filled in the closed pipe.

As an example, the heat transfer medium is fluid, preferably, the heat transfer medium may be gas or liquid or a mixture of liquid and gas. More preferably, in this embodiment, the heat transfer medium is a mixture of liquid and gas.

As an example, the shape of the closed pipe may be a hexagonal cellular shape, a circular cellular shape, a quadrilateral cellular shape, a shape formed by a plurality of U in tandem, a rhombic shape, a triangular shape, a circular ring shape or any combination of more than one of the shapes.

As an example, the material of the phase change inhibition heat dissipation plate 223 may be copper, copper alloy, aluminum, aluminum alloy, titanium, titanium alloy, stainless steel or any combination of more than one of the materials.

As an example, the thickness of the phase change inhibition heat dissipation plate 223 and the inner diameter of the closed pipe may be set according to actual situation. Preferably, in this embodiment, the thickness of the phase change inhibition heat dissipation plate 223 is 0.2 mm-3 mm, and the inner diameter of the closed pipe is 0.1 mm-1 mm.

As an example, surfaces of fitting parts between the phase change inhibition heat dissipation plate 223 and the P-type thermoelectric element 221 and the N-type thermoelectric element 222 are flat, and heat transfer enhancing structures such as holes, shallow slots, protrusions or shutters or covering heat transfer enhancing coating layers are formed in or on surfaces of other parts of the phase change inhibition heat dissipation plate 223 to enhance the heat transfer capability of the phase change inhibition heat dissipation plate 223. Here, other parts of the phase change inhibition heat dissipation plate 223 refer to parts, at which the P-type thermoelectric element 221 and the N-type thermoelectric element 222 are exposed, of the phase change inhibition heat dissipation plate 223.

As an example, the phase change inhibition heat dissipation plate 223 may comprise two stacked metal plates. A closed pipe having a certain shape is formed in one metal plate. A heat transfer medium is filled in the closed pipe. A fluid medium pipe having a certain shape is formed in the other metal plate. Openings are formed in both ends of the fluid medium pipe, and the openings are adapted to be interconnected with a fluid medium source. By designing the phase change inhibition heat dissipation plate 223 to be a dual-layer structure comprising a metal layer adapted to be used as a phase change inhibition pipe and a metal layer comprising a fluid medium pipe, the heat transmitted by the phase change inhibition heat dissipation plate 223 can be rapidly dissipated out by using a proper flowing medium.

The phase change inhibition heat dissipation plate 223 has extremely high effective heat conductivity, and can rapidly transfer high-heat-flux heat from a heat source to a heat sink. In this embodiment, the phase change inhibition heat dissipation plate 223 can rapidly and uniformly dissipate heat emitted by the thermoelectric element from the heat dissipation plate to a space, or transfer the heat to a flowing medium.

As an example, the phase change inhibition heat collection plate 224 comprises a metal plate. A closed pipe having a certain shape is formed in the metal plate through a blowing process. A heat transfer medium is filled in the closed pipe.

As an example, the heat transfer medium is fluid, preferably, the heat transfer medium may be gas or liquid or a mixture of liquid and gas. More preferably, in this embodiment, the heat transfer medium is a mixture of liquid and gas.

As an example, the shape of the closed pipe may be a hexagonal cellular shape, a circular cellular shape, a quadrilateral cellular shape, a shape formed by a plurality of U in tandem, a rhombic shape, a triangular shape, a circular ring shape or any combination of more than one of the shapes.

As an example, the material of the phase change inhibition heat collection plate 224 may be copper, copper alloy, aluminum, aluminum alloy, titanium, titanium alloy, stainless steel or any combination of more than one of the materials.

As an example, the thickness of the phase change inhibition heat collection plate 224 and the inner diameter of the closed pipe may be set according to the actual situation. Preferably, in this embodiment, the thickness of the phase change inhibition heat collection plate 224 is 0.2 mm-3 mm, and the inner diameter of the closed pipe is 0.1 mm-1 mm.

As an example, surfaces of fitting parts between the phase change inhibition heat collection plate 224 and the P-type thermoelectric element 221 and the N-type thermoelectric element 222 are flat, and heat transfer enhancing structures such as holes, shallow slots, protrusions or shutters or covering heat transfer enhancing coating layers are formed in or on surfaces of other parts of the phase change inhibition heat collection plate 224 to enhance the heat transfer capability of the phase change inhibition heat collection plate 224. Here, other parts of the phase change inhibition heat collection plate 224 refer to parts, at which the P-type thermoelectric element 221 and the N-type thermoelectric element 222 are exposed, of the phase change inhibition heat collection plate 224.

As an example, the phase change inhibition heat collection plate 224 may comprise two stacked metal plates. A closed pipe having a certain shape is formed in one metal plate. A heat transfer medium is filled in the closed pipe. A fluid medium pipe having a certain shape is formed in the other metal plate. Openings are formed in both ends of the fluid medium pipe, and the openings are adapted to be interconnected with a fluid medium source. By designing the phase change inhibition heat collection plate 224 to be a dual-layer structure comprising a metal layer adapted to be used as a phase change inhibition pipe and a metal layer comprising a fluid medium pipe, the heat of the heat source can be transferred to the phase change inhibition heat collection plate 224 by using a proper flowing medium, and then is rapidly and uniformly transferred to the thermoelectric element.

The phase change inhibition heat collection plate 224 has extremely high effective heat conductivity, and can rapidly transfer high-heat-flux heat from a heat source to a heat sink. In this embodiment, the phase change inhibition heat collection plate 224 can rapidly and uniformly transfer heat emitted by the heat source to the thermoelectric element.

As an example, the phase change inhibition heat transfer thermoelectric power generation device comprises a plurality of thermoelectric unit bodies 22, and the plurality of thermoelectric unit bodies 22 are serially combined and integrated to form the phase change inhibition heat transfer thermoelectric power generation device. FIG. 4 is only an example comprising five pairs of thermoelectric unit bodies 22, but this embodiment is not limited thereto. In this embodiment, the number of the thermoelectric unit bodies 22 in the phase change inhibition heat transfer thermoelectric power generation device may be set according to the actual need. By combining the plurality of thermoelectric unit bodies 22, higher output voltage and output power can be obtained.

As an example, both sides of the phase change inhibition heat transfer thermoelectric power generation device are respectively provided with a DBC ceramic plate 21. The DBC ceramic plate 21 on one side of the phase change inhibition heat transfer thermoelectric power generation device is fit with surfaces of the phase change inhibition heat dissipation plates 223 in the thermoelectric unit bodies 22, and the DBC ceramic plate 21 on another side of the phase change inhibition heat transfer thermoelectric power generation device is connected with the P-type thermoelectric elements 221 or the N-type thermoelectric elements 222 in the thermoelectric unit bodies 22 through one phase change inhibition heat dissipation plates 223. The DBC ceramic plates 21 on both sides of the phase change inhibition heat transfer thermoelectric power generation device are only used as electrical insulation materials for isolation from the outside; the phase change inhibition heat dissipation plates 223 fitted with the two DBC ceramic plates 21 are respectively used as a positive electrode 23 and a negative electrode 24.

As an example, the P-type thermoelectric elements 221, the N-type thermoelectric elements 222, the phase change inhibition heat dissipation plates 223, the phase change inhibition heat collection plates 224 and the DBC ceramic plates 21 are fixedly connected through a soldering, brazing, crimping, friction welding or pressure welding process. The integration process of the thermoelectric power generation device formed by the P-type thermoelectric elements 221, the N-type thermoelectric elements 222, the phase change inhibition heat dissipation plates 223, the phase change inhibition heat collection plates 224 and the DBC ceramic plates 21 may be implemented in atmosphere, may also be implemented in a vacuum environment, and may also be implemented in the environment protected by an inert gas and controlled by temperature. It needs to be stated that the integration process of the thermoelectric power generation device shall take into account the compatibility with the phase change inhibition heat dissipation plates 223, the phase change inhibition heat collection plates 224 and the medium filling process thereof.

In the phase change inhibition heat transfer thermoelectric power generation device provided by the present invention, one P-type thermoelectric element and one N-type thermoelectric element are isolated from each other through one phase change inhibition heat collection plate and one phase change inhibition heat dissipation plate to form a pair of thermoelectric unit bodies. A plurality of thermoelectric unit bodies are serially combined and integrated to form a thermoelectric device, and no electrical isolation is needed thereamong. Integrated phase change inhibition heat transfer plates not only serve as electrodes of thermoelectric unit bodies, but also serve as heat collection plates and heat dissipation plates. The contact thermal resistance between the ceramic plates and the heat exchangers on the hot side and the cold side, the thermal resistance of the ceramic plates and the contact thermal resistance between the ceramic plates and the electrodes are removed from a heat path of the phase change inhibition heat transfer thermoelectric power generation device provided by the present invention, which is helpful to establish temperature difference. Therefore, the heat utilization ratio is greatly improved, and the heat-electricity conversion efficiency of the thermoelectric power generation device is finally improved.

### Embodiment 2

Please refer to FIG. 5. The present invention further provides a method for manufacturing a phase change inhibition heat transfer thermoelectric power generation device. The manufacturing method comprises the following steps:

S1: manufacturing P-type thermoelectric elements and N-type thermoelectric elements;

S2: manufacturing phase change inhibition heat dissipation plates;

S3: manufacturing phase change inhibition heat collection plates;

S4: preparing DBC ceramic plates; and

S5: arranging the P-type thermoelectric elements, the N-type thermoelectric elements, the phase change inhibition heat dissipation plates, the phase change inhibition heat collection plates and the DBC ceramic plates in parallel, the phase change inhibition heat collection plates being located between the P-type thermoelectric elements and the N-type thermoelectric elements, the phase change inhibition heat dissipation plates being located on one side, far away from the phase change inhibition heat collection plates, of the P-type thermoelectric elements and the N-type thermoelectric elements, and the DBC ceramic plates being located on outer sides of the outermost phase change inhibition heat dissipation plates; and fixedly connecting the P-type thermoelectric elements, the N-type thermoelectric elements, the phase change inhibition heat dissipation plates, the phase change inhibition heat collection plates and the DBC ceramic plates.

Step S1 is executed. Please refer to step S1 in FIG. 5 to manufacture P-type thermoelectric elements and N-type thermoelectric elements.

As an example, a specific method for manufacturing the P-type thermoelectric elements and the N-type thermoelectric elements comprises the following steps:

S11: respectively preparing a material of the P-type thermoelectric elements and a material of the N-type thermoelectric elements according to certain components and proportions, taking the manufacture of a bismuth telluride thermoelectric power generation device as an example, the prepared material of the P-type thermoelectric elements is a pseudobinary thermoelectric material with components (70%-80%) Sb²Te₃-(20%-30%) Bi₂Te₂, added with excessive Te having weight which accounts for 1%-5% of total weight; the prepared material of the N-type thermoelectric elements is a pseudobinary thermoelectric material with components (85%-98%) Bi₂Te₃-(2%-15%) Bi₂Se₂, doped with SbI₃ or TeI₄ having weight less than 1% of total weight; and the percentage is weight percentage of each part in the components;

S12: respectively manufacturing thermoelectric rods with certain diameter (such as 30 mm) by using the prepared material of the P-type thermoelectric elements and the prepared material of the N-type thermoelectric elements according to a conventional zone melting growth process;

S13: cutting the thermoelectric rods into thermoelectric elements with certain thickness (such as 1.6 mm) by using an inside diameter slicer, an outside diameter slicer or a wire cutter;

S14: spray-coating an Ni layer with thickness of 3 μm-60 μm onto the thermoelectric elements; and

S15: electroplating or chemically plating an Sn layer with thickens of 1 μm-3 μm onto the Ni layer.

As an example, a specific method for manufacturing the P-type thermoelectric elements and the N-type thermoelectric elements comprises the following steps:

S11: respectively preparing a material of the P-type thermoelectric elements and a material of the N-type thermoelectric elements according to certain components and proportions, taking the manufacture of a bismuth telluride thermoelectric power generation device as an example, the prepared material of the P-type thermoelectric elements is a pseudobinary thermoelectric material with components (70%-80%) Sb₂Te₃-(20%-30%) Bi₂Te₂, added with excessive Te having weight which accounts for 1%-5% of total weight; the prepared material of the N-type thermoelectric elements is a pseudobinary thermoelectric material with components (85%-98%) Bi₂Te₃-(2%-15%) Bi₂Se₂, doped with SbI₃ or TeI₄ having weight less than 1% of total weight; and the percentage is weight percentage of each part in the components;

S12: respectively manufacturing block materials by using the prepared material of the P-type thermoelectric elements and the prepared material of the N-type thermoelectric elements through hot-pressing, an SPS process, a mechanical alloying method or other powder metallurgical processes;

S13: cutting the block materials into thermoelectric elements with certain thickness (such as 1.6 mm) by using an inside diameter slicer, an outside diameter slicer or a wire cutter;

S14: spraying an Ni layer with thickness of 3 μm-60 μm onto the thermoelectric elements; and

S15: electroplating or chemically plating an Sn layer with thickens of 1 μm-3 μm onto the Ni layer.

Step S2 is executed. Please refer to step S2 in FIG. 5 to manufacture phase change inhibition heat dissipation plates.

As an example, after the phase change inhibition heat dissipation plates are manufactured, the method further comprises a step of performing metallization treatment to the phase change inhibition heat dissipation plates.

Step S3 is executed. Please refer to step S3 in FIG. 5 to manufacture phase change inhibition heat collection plates.

As an example, after the phase change inhibition heat collection plates are manufactured, the method further comprises a step of performing metallization treatment to the phase change inhibition heat collection plates.

Step S4 is executed. Please refer to step S4 in FIG. 5 to prepare DBC (Direct Bond Coper) ceramic plates.

It needs to be states that a sequence of step S1 of manufacturing the P-type thermoelectric elements and the N-type thermoelectric elements, step S2 of manufacturing the phase change inhibition heat dissipation plates, step S3 of manufacturing the phase change inhibition heat collection plates and step S4 of preparing the DBC ceramic plates may be adjusted according to the actual need. The sequence here is only used as an example, and this embodiment is not limited thereto.

As an example, the method further comprises a step of cleaning the DBC ceramic plates.

Step S5 is executed. Please refer to step S5 in FIG. 5. The P-type thermoelectric elements, the N-type thermoelectric elements, the phase change inhibition heat dissipation plates, the phase change inhibition heat collection plates and the DBC ceramic plates are arranged in parallel. The phase change inhibition heat collection plates are located between the P-type thermoelectric elements and the N-type thermoelectric elements. The phase change inhibition heat dissipation plates are located on one side, far away from the phase change inhibition heat collection plates, of the P-type thermoelectric elements and the N-type thermoelectric elements. The DBC ceramic plates are located on outer sides of the outermost phase change inhibition heat dissipation plates. The P-type thermoelectric elements, the N-type thermoelectric elements, the phase change inhibition heat dissipation plates, the phase change inhibition heat collection plates and the DBC ceramic plates are fixedly connect.

As an example, the P-type thermoelectric elements, the N-type thermoelectric elements, the phase change inhibition heat dissipation plates, the phase change inhibition heat collection plates and the DBC ceramic plates are fixedly connected through a soldering, brazing, crimping, friction welding or pressure welding process.

As an example, the integration process of the thermoelectric power generation device formed by the P-type thermoelectric elements, the N-type thermoelectric elements, the phase change inhibition heat dissipation plates, the phase change inhibition heat collection plates and the DBC ceramic plates may be implemented in atmosphere, may also be implemented in a vacuum environment, and may also be implemented in the environment protected by an inert gas and controlled by temperature. It needs to be stated that the integration process of the thermoelectric power generation device shall take into account the compatibility with the phase change inhibition heat dissipation plates, the phase change inhibition heat collection plates and the medium filling process thereof.

As an example, 95% PB-5% Sn welding paste having certain thickness may be coated on both sides of the P-type thermoelectric elements, the N-type thermoelectric elements, the phase change inhibition heat dissipation plates, the phase change inhibition heat collection plates and the DBC ceramic plates. The P-type thermoelectric elements, the N-type thermoelectric elements, the phase change inhibition heat dissipation plates, the phase change inhibition heat collection plates and the DBC ceramic plates are arranged according to a certain sequence, and then they are fixed by using welding fixtures, placed into a nitrogen gas shielded welding furnace, and welded into an integral body of the thermoelectric power generation device.

As an example, the number and the arrangement sequence of the P-type thermoelectric elements, the N-type thermoelectric elements, the phase change inhibition heat dissipation plates, the phase change inhibition heat collection plates and the DBC ceramic plates manufactured in this embodiment may be as illustrated in FIG. 4 in embodiment 1, i.e., the illustrated number of the P-type thermoelectric elements, the N-type thermoelectric elements, and the phase change inhibition heat collection plates is five, the number of the phase change inhibition heat dissipation plates is six, and the number of the DBC ceramic plates is two. However, this embodiment is not limited thereto, and the number and the arrangement sequence of the P-type thermoelectric elements, the N-type thermoelectric elements, the phase change inhibition heat dissipation plates, the phase change inhibition heat collection plates and the DBC ceramic plates may be adjusted according to actual need. It needs to be stated that, no matter how the arrangement sequence of the P-type thermoelectric elements, the N-type thermoelectric elements, the phase change inhibition heat dissipation plates, the phase change inhibition heat collection plates and the DBC ceramic plates manufactured is adjusted, it must be guaranteed that the P-type thermoelectric elements and the N-type thermoelectric elements are isolated by the phase change inhibition heat dissipation plates and the phase change inhibition heat collection plates, and the DBC ceramic plates are located on the two outermost sides of the entire structure.

Taking the phase change inhibition heat transfer thermoelectric power generation device illustrated in FIG. 4 as an example, if the area of the phase change inhibition heat dissipation plates and the phase change inhibition heat collection plates is not considered, the size of the phase change inhibition heat transfer thermoelectric power generation device is as follow: cross section area: 40 mm*40 mm, thickness: less than 15 mm. When the temperature difference between the cold side and the hot side is 200° C., the maximum output power may reach 85 W. A comparable model is thermoelectric power generation TEG1-127-1.4-1.6, which is a commercial bismuth telluride thermoelectric power generation module. The external size thereof is as follow: area: 40 mm*40 mm, height: 3.2 mm; the size of each thermoelectric element is as follow: cross section area: 1.4 mm*1.4 mm, height: 1.6 mm; the area of each electrode is 1.6 mm*2.4 mm; and the number of pairs of thermoelectric elements is 127. For this power generation module, when the temperature difference between the cold side and the hot side is 200° C., the maximum output power is 5.8 W. Accordingly, it can be seen that, under the same condition of temperature difference, the maximum output power of the thermoelectric power generation device formed by five pairs of thermoelectric unit bodies in FIG. 4 of the present invention is 14.6 times of the maximum output power of the TEG1-127-1.4-1.6 thermoelectric power generation module.

For the thermoelectric elements in the phase change inhibition heat transfer thermoelectric power generation device provided by the present invention, rods grown through zone melting or block materials manufactured through hot-pressing or other powder metallurgical process are cut into sheets, are subjected to a proper surface treatment process and then directly used as the thermoelectric elements. This process is different from the traditional thermoelectric element manufacturing process, i.e., manufacturing thermoelectric elements with a relative small rectangular section through a cutting process by using sheets. Thus, the manufacturing process of the thermoelectric module is simplified, the material utilization ratio is improved, and the consumption and costs of raw materials are greatly reduced.

To sum up, by adopting the phase change inhibition heat transfer thermoelectric power generation device and the method for manufacturing the same provided by the present invention, in the phase change inhibition heat transfer thermoelectric power generation device provided by the present invention, one P-type thermoelectric element and one N-type thermoelectric element are isolated from each other through one phase change inhibition heat collection plate and one phase change inhibition heat dissipation plate to form a pair of thermoelectric unit bodies. A plurality of thermoelectric unit bodies are serially combined and integrated to form a thermoelectric device, and no electrical isolation is not needed thereamong. Integrated phase change inhibition heat transfer plates not only serve as electrodes of thermoelectric unit bodies, but also serve as heat collection plates and heat dissipation plates. By adopting the phase change inhibition heat transfer thermoelectric power generation device provided by the present invention, the thermal resistance of ceramic plates and the contact thermal resistance between the ceramic plate and an electrode interface are decreased in a heat circuit, which is helpful to establish temperature difference. Since the phase change inhibition heat transfer plate serves as both an electrode and a heat exchanger between a hot side and a cold side, the interface thermal resistance is smaller and the heat-electricity conversion efficiency of the thermoelectric power generator is greatly improved. By combining a plurality of thermoelectric unit bodies, higher output voltage and output power can be obtained. For the thermoelectric elements in the phase change inhibition heat transfer thermoelectric power generation device provided by the present invention, rods grown through zone melting or block materials manufactured through hot-pressing or other powder metallurgical process are cut into sheets, subjected to a proper surface treatment process, and then directly used as the thermoelectric elements. This process is different from the traditional thermoelectric element manufacturing process, i.e., manufacturing thermoelectric elements with a relative small rectangular section through a cutting process by using sheets. Thus, the manufacturing process of the thermoelectric module is simplified, the material utilization ratio is improved, and the consumption and costs of raw materials are greatly reduced.

The above-mentioned embodiments are just used for exemplarily describing the principle and the effect of the present invention instead of limiting the present invention. One skilled in the art may make modifications or variations to the above-mentioned embodiments without departing from the spirit and scope of the present invention. Therefore, all equivalent modifications or variations made by one skilled in the art without departing from the spirit and technical concept disclosed by the present invention shall be also covered by the claims of the present invention.

1. A phase change inhibition heat transfer thermoelectric power generation device, characterized in that the phase change inhibition heat transfer thermoelectric power generation device comprises at least one thermoelectric unit body; the thermoelectric unit body comprises a P-type thermoelectric element, an N-type thermoelectric element, a phase change inhibition heat dissipation plate and a phase change inhibition heat collection plate;
the P-type thermoelectric element, the N-type thermoelectric element, the phase change inhibition heat dissipation plate and the phase change inhibition heat collection plate are arranged in parallel; the phase change inhibition heat collection plate is located between the P-type thermoelectric element and the N-type thermoelectric element; the phase change inhibition heat dissipation plate is located on one side, far away from the phase change inhibition heat collection plate, of the P-type thermoelectric element or the N-type thermoelectric element; and the P-type thermoelectric element, the N-type thermoelectric element, the phase change inhibition heat dissipation plate and the phase change inhibition heat collection plate are closely fit.

2. The phase change inhibition heat transfer thermoelectric power generation device according to claim 1, characterized in that each of the phase change inhibition heat dissipation plate and the phase change inhibition heat collection plate comprises a metal plate; a closed pipe having a certain shape is formed in the metal plate; and a heat transfer medium is filled in the closed pipe.

3. The phase change inhibition heat transfer thermoelectric power generation device according to claim 1, characterized in that each of the phase change inhibition heat dissipation plate and the phase change inhibition heat collection plate comprises two stacked metal plates; and a closed pipe having a certain shape is formed in one metal plate; a heat transfer medium is filled in the closed pipe; a fluid medium pipe having a certain shape is formed in the other metal plate; openings are formed at two ends of the fluid medium pipe; and the openings are adapted to be interconnected with a fluid medium source.

4. The phase change inhibition heat transfer thermoelectric power generation device according to claim 2 or 3, characterized in that the shape of the closed pipe is a hexagonal cellular shape, a circular cellular shape, a quadrilateral cellular shape, a shape formed by a plurality of U in tandem, a rhombic shape, a triangular shape, a circular ring shape or any combination of more than one of the shapes.

5. The phase change inhibition heat transfer thermoelectric power generation device according to claim 1, characterized in that materials of both the phase change inhibition heat dissipation plate and the phase change inhibition heat collection plate are copper, copper alloy, aluminum, aluminum alloy, titanium, titanium alloy, stainless steel or any combination of more than one of the materials.

6. The phase change inhibition heat transfer thermoelectric power generation device according to claim 1, characterized in that materials of the P-type thermoelectric element and the N-type thermoelectric element are doped pseudobinary bismuth telluride and solid solution thereof, pseudoternary bismuth telluride and solid solution thereof, doped lead telluride and solid solution thereof, germanium telluride and solid solution thereof, single-filled or multi-filled skutterudite thermoelectric materials, Half-Heusler thermoelectric materials, doped Si—Ge alloy and Zintl phase thermoelectric materials.

7. The phase change inhibition heat transfer thermoelectric power generation device according to claim 1, characterized in that surfaces of fitting parts between the phase change inhibition heat dissipation plate and the phase change inhibition heat collection plate, and between the P-type thermoelectric element and the N-type thermoelectric element are flat; and holes, shallow slots, protrusions, shutters or covering coating layers are formed in or on surfaces of other parts of the phase change inhibition heat dissipation plate and the phase change inhibition heat collection plate to enhance heat transfer.

8. The phase change inhibition heat transfer thermoelectric power generation device according to claim 1, characterized in that the phase change inhibition heat transfer thermoelectric power generation device comprises a plurality of thermoelectric unit bodies; and the plurality of thermoelectric unit bodies are serially combined and integrated to form the phase change inhibition heat transfer thermoelectric power generation device.

9. The phase change inhibition heat transfer thermoelectric power generation device according to claim 8, characterized in that both sides of the phase change inhibition heat transfer thermoelectric power generation device are respectively provided with a DBC ceramic plate; the DBC ceramic plate on one side of the phase change inhibition heat transfer thermoelectric power generation device is fit with surfaces of the phase change inhibition heat dissipation plates in the thermoelectric unit bodies; and the DBC ceramic plate on the other side of the phase change inhibition heat transfer thermoelectric power generation device is connected with the P-type thermoelectric elements or the N-type thermoelectric elements in the thermoelectric unit bodies through one phase change inhibition heat dissipation plates.

10. The phase change inhibition heat transfer thermoelectric power generation device according to claim 9, characterized in that the P-type thermoelectric elements, the N-type thermoelectric elements, the phase change inhibition heat dissipation plates, the phase change inhibition heat collection plates and the DBC ceramic plates are fixedly connected through a soldering, brazing, crimping, friction welding or pressure welding process.

11. A method for manufacturing a phase change inhibition heat transfer thermoelectric power generation device, characterized in that the method comprises the following steps:
manufacturing P-type thermoelectric elements and N-type thermoelectric elements;
manufacturing phase change inhibition heat dissipation plates;
manufacturing phase change inhibition heat collection plates;
preparing DBC ceramic plates;
arranging the P-type thermoelectric elements, the N-type thermoelectric elements, the phase change inhibition heat dissipation plates, the phase change inhibition heat collection plates and the DBC ceramic plates in parallel; the phase change inhibition heat collection plates being located between the P-type thermoelectric elements and the N-type thermoelectric elements; the phase change inhibition heat dissipation plates being located on one side, far away from the phase change inhibition heat collection plates, of the P-type thermoelectric elements and the N-type thermoelectric elements; the DBC ceramic plates being located on outer sides of the outermost phase change inhibition heat dissipation plates; and fixedly connecting the P-type thermoelectric elements, the N-type thermoelectric elements, the phase change inhibition heat dissipation plates, the phase change inhibition heat collection plates and the DBC ceramic plates.

12. The method for manufacturing the phase change inhibition heat transfer thermoelectric power generation device according to claim 11, characterized in that a specific method for manufacturing the P-type thermoelectric elements and the N-type thermoelectric elements comprises the following steps:
respectively preparing a material of the P-type thermoelectric elements and a material of the N-type thermoelectric elements according to certain components and proportions;
respectively manufacturing thermoelectric rods by using the prepared material of the P-type thermoelectric elements and the prepared material of the N-type thermoelectric elements according to a conventional zone melting growth process;
cutting the thermoelectric rods into thermoelectric elements by using an inside diameter slicer, an outside diameter slicer or a wire cutter;
electroplating or spray-coating an Ni layer, an Ni alloy layer, an Mo layer, an Mo alloy layer, a Ti layer or a Ti alloy layer as a buffer layer onto the thermoelectric elements; and
electroplating or chemically plating an Sn layer onto the buffer layer.

13. The method for manufacturing the phase change inhibition heat transfer thermoelectric power generation device according to claim 11, characterized in that a specific method for manufacturing the P-type thermoelectric elements and the N-type thermoelectric elements comprises the following steps:
respectively preparing a material of the P-type thermoelectric elements and a material of the N-type thermoelectric elements according to certain components and proportions;
respectively manufacturing block materials by using the prepared material of the P-type thermoelectric elements and the prepared material of the N-type thermoelectric elements through hot-pressing, an SPS process, a mechanical alloying method or other powder metallurgical processes;
cutting the block materials into thermoelectric elements by using an inside diameter slicer, an outside diameter slicer or a wire cutter;
electroplating or spray-coating an Ni layer, an Ni alloy layer, an Mo layer, an Mo alloy layer, a Ti layer or a Ti alloy layer as a buffer layer onto the thermoelectric elements; and
electroplating or chemically plating an Sn layer onto the buffer layer.

14. The method for manufacturing the phase change inhibition heat transfer thermoelectric power generation device according to claim 11, characterized in that, after the phase change inhibition heat dissipation plates and the phase change inhibition heat collection plates are manufactured, the method further comprises a step of performing metallization treatment to the phase change inhibition heat dissipation plates and the phase change inhibition heat collection plates.

15. The method for manufacturing the phase change inhibition heat transfer thermoelectric power generation device according to claim 11, characterized in that the P-type thermoelectric elements, the N-type thermoelectric elements, the phase change inhibition heat dissipation plates, the phase change inhibition heat collection plates and the DBC ceramic plates are fixedly connected through a soldering, brazing, crimping, friction welding or pressure welding process.

16. The phase change inhibition heat transfer thermoelectric power generation device according to claim 3, characterized in that the shape of the closed pipe is a hexagonal cellular shape, a circular cellular shape, a quadrilateral cellular shape, a shape formed by a plurality of U in tandem, a rhombic shape, a triangular shape, a circular ring shape or any combination of more than one of the shapes.
